(19) United States
(12) Patent Application Publication
(10) Pub. No.: US 2026/0072077 A1
(43) Pub. Date: Mar. 12, 2026

(54) TEST CONTACT FOR A PIN-TYPE DEVICE WITH A SQUARE OR ROUND CROSS-SECTION

(71) Applicant: JF MICROTECHNOLOGY SDN. BHD., Petaling Jaya (MY)

(72) Inventors: Wei Kuong FOONG, Petaling Jaya (MY); Kok Sing GOH, Petaling Jaya (MY); Shamal MUNDIYATH, Petaling Jaya (MY); Eng Kiat LEE, Petaling Jaya (MY); Kee Shan GOH, Petaling Jaya (MY)

(73) Assignee: JF MICROTECHNOLOGY SDN. BHD., Petaling Jaya (MY)

(21) Appl. No.: 19/176,891

(22) Filed: Apr. 11, 2025

(30) Foreign Application Priority Data
Apr. 13, 2024 (MY) PI2024002164

(51) Int. Cl. G01R 31/28

(52) U.S. Cl. CPC G01R 31/2884

(57) ABSTRACT

An electrical contact for electrically connecting a device pin of an integrated circuit (IC) device-under-test and a load board of the testing apparatus, the electrical contact having a crossed pair of contact pins with each pin having a pair of upwards-extending arms that intersect perpendicularly the pair of arms of the other pin, so that all four arms form a square configuration, with each arm at a 90° angle to the arm next to it. A top pin has a bridge that saddles between the arms, and over a shoulder of the bottom pin, so that the top and bottom pins are not in contact with each other.

### FIELD OF INVENTION

The present invention relates generally to an electrical test contact for testing an integrated circuit (IC) device with pin-type leads, and more specifically to such a contact for testing an IC device with pin-type leads that have a square, round or similar cross-section.

BACKGROUND OF INVENTION

Integrated circuit (IC) devices are tested to evaluate their performance as part of the manufacturing process. In these tests, the pins of the devices must be electrically connected to a load board of the testing apparatus when they are lowered down to the load board. This is achieved using an electrical contact fixed to the load board. The electrical contact must be able to receive and establish a good electrical connection with the device pin in a repeatable fashion over a high number of rapid tests. The problem is, devices with pin-type leads are usually installed or soldered independently onto the devices as a distinct part of the manufacturing process. This affects the positional accuracy and dimensional tolerances of the device pin, which makes establishing a good electrical connection between the device pin and the load board a challenge for traditional designs of electrical test contact terminals. Some of these tests also require very high electrical currents to run through these electrical contact terminals, which makes the quality and precision of the electrical connection even more crucial.

One solution for an electrical contact with pin-type leads is taught by Foong, et al in Malaysian patent application no. PI2023000870. In this design, the electrical contact comprises two contact pins placed parallel to each other. Each contact pin has a pair of forked arms which extend upwards to grip the device pin. This design works very well with device pins of the traditional eagle eye variety. The oblong shape of the pin head in these types of device pins favour the parallel contact pin design taught by Foong, et al, as more surface area is available to both contact pins. However, this parallel contact pin design does not perform well with device pins that have round or square cross-sections. Device pins that have a round or square cross-section do not establish a good electrical connection with the parallel contact pin design taught by Foong, et al, and sometimes miss one contact pin altogether. This is clearly a problem for kelvin testing where one contact pin is for force and the other for sense, and contacting both pins is crucial for a successful test. If the device pin misses one contact pin, the test result will be void. Round cross-sectioned device pins offer a very small contact area between the device pin and the contact pins, which results in a failed test or inaccurate results. Square cross-sectioned device pins must be in a very precise rotation along the vertical axis so that the sides of the square are flush with the contact pins to achieve the best electrical connection. If the square cross-sectioned device pin is rotated by 45° to that optimal angle, only two corners of the device pin will be in contact with the contact pins, which is not ideal for a good electrical connection. If the device pin has a lateral deviation during a test, meaning it strays laterally from a desired or optimal position, the parallel design is not very forgiving if the deviation is along the parallel axis of the contact pins. In this case, the device pin has a high chance of missing one contact pin entirely. This also leads to either a failed test or inaccurate results.

What is needed in the art is an electrical test contact in an IC device testing apparatus that provides a good electrical connection for round and square cross-sectioned device pins, and for device pins that have a lateral deviation or that stray from a desired datum position.

### SUMMARY OF INVENTION

The present invention seeks to overcome the afore-mentioned disadvantages by providing an electrical contact for electrically connecting a device pin of an integrated circuit (IC) device-under-test and a load board of the testing apparatus, the electrical contact having a crossed pair of contact pins with each pin having a pair of upwards-extending arms that intersect perpendicularly with the pair of arms of the other pin, so that all four arms form a square configuration, with each arm at a 90° angle to the arm next to it. A top pin has a bridge that saddles between the arms, and over a shoulder of the bottom pin, so that the top and bottom pins are not in contact with each other.

This invention thus relates to an electrical contact in a testing apparatus for detachably connecting with an IC device pin, comprising: a top pin extending along a vertical axis (ZZ) between an upper and a lower end and having a forked pair of arms extending upwards from a bridge and ending in top pin arm tips, said top pin arm tips adapted to receive the device pin in between thereof, and the top pin arm tips having an inward bias so as to establish a good electrical connection with the device pin, and the top pin having a means of establishing an electrical connection with a load board of the testing apparatus; and a bottom pin also extending along the vertical axis (ZZ) between the upper and lower ends and also having a forked pair of arms extending upwards from a shoulder and ending in bottom pin arm tips, said bottom pin arm tips substantially at the same height as the top pin arms tips and said bottom pin arm tips adapted to receive the device pin in between thereof and having an inward bias so as to establish a good electrical connection with the device pin, and the bottom pin having a means of establishing an electrical connection with the load board of the testing apparatus. The top pin arms are forked in a direction that is substantially perpendicular to the direction in which the bottom pin arms are forked, so that each arm tip is at a 90°angle to the one next to it, when viewed along the vertical axis.

In a preferred embodiment, the top pin's means of establishing an electrical connection with the load board comprises a forked pair of legs extending downwards from the bridge, the top pin legs forked in a direction parallel to the direction in which the top pin arms are forked, and the bottom pin's means of establishing an electrical connection with the load board also comprises a forked pair of legs extending downwards from the shoulder, the legs then connecting with the load board terminal, the bottom pin legs also forked in a direction parallel to the direction in which the bottom pin arms are forked.

In another preferred embodiment, the top pin's means of establishing an electrical connection with the load board comprises a forked pair of legs extending downwards from the bridge, the top pin legs forked in a direction parallel to the direction in which the top pin arms are forked, and the bottom pin's means of establishing an electrical connection with the load board comprises one leg extending downwards from the shoulder, the leg then connecting with the load board terminal.

The top pin's bridge saddles across the bottom pin's shoulder, but they do not contact each other. In fact, there is no direct contact between the top pin and the bottom pin. To ensure there is no contact between the bridge and the shoulder, a retainer bridge made from an electrically insulative material is placed in between the bridge and the shoulder, the retainer bridge physically keeping the bridge and shoulder separate.

In another preferred embodiment, the present invention further comprises two plates located at an intermediate height along the top and bottom pins above the bridge, each plate provided with at least one hole, and through which holes the top pin and bottom pin arms pierce. The holes in the plates are adapted in their shape to limit horizontal movement of the arms to within a desired range.

In yet another preferred embodiment, each arm is provided on an inside surface thereof with a relief cavity just below its arm tip, said relief cavity allowing only a portion of the inside surface near the upper end of the arms to be in contact with the device pin. This significantly reduces the stresses on the arms during a test.

During a test, as the device pin of the IC device-under-test is lowered towards the contact pins, it electrically connects with all four arms in most circumstances. However, even under the most extreme of lateral deviations or other positional anomalies of the device pin, it still electrically connects with at least one top pin arm and at least one bottom pin arm. In a Kelvin test, this ensures contact of the device pin with both force and sense pins, thus ensuring a much higher rate of successful tests.

In yet another preferred embodiment, the load board is provided with terminals for electrically connecting with both the top pin's and the bottom pin's means of establishing an electrical connection with a load board of the testing apparatus, wherein each said terminal comprises an electrically conductive hole adapted to snugly receive the said means. For embodiments where the top pin's and bottom pin's means comprises legs, the load board terminal would be a hole or holes that snugly receive those legs to a depth of the holes, so that a good electrical connection between the load board terminals and contact pins is established.

In yet another preferred embodiment, the load board is provided with terminals for electrically connecting with both the top pin's and the bottom pin's legs, wherein each said terminal comprises an electrically conductive hole adapted to receive one leg to a depth sufficient to establish a desired amount of electrical connection between the load board terminal and the leg.

Alternatively, the holes may not necessarily be tight or snug for the legs if there are other ways to establish that electrical connection, such as the legs having an inward or outward bias when inserted into the load board terminals that provides more force between the contact points.

This invention thus provides an elegant and effective solution to the problem of round and square cross-sectioned device pins establishing good electrical contact with the test contact pins. The intrinsic arrangement and geometry of the crossed contacts pins of this invention ensures a good electrical connection between the contact pins and these types of device pins. Even device pins of these cross-sectional shapes that have a large positional deviation have a better chance of establishing at least the required electrical connection with the contact pins of this invention, when compared to other designs.

This invention also provides a solution to the problem of a device pin with lateral deviation from a desired position not establishing electrical connection with both the force and sense contacts in a Kelvin test. Since the contact pins are in a square configuration, it does not favour any one direction, but allows deviation of the device pin equally in all directions.

The problem of space constraint that is derived from placing two contacts so close to each other in a parallel design is eliminated by the crossed contact pin design, since the contacts are not competing for the same space next to each other, but are sharing the space with one another. Other objects and advantages will be more fully apparent from the following disclosure and appended claims.

### BRIEF DESCRIPTION OF DRAWINGS

FIG. 1a shows a round cross-sectioned device pin nominally engaging a known test contact terminal.

FIG. 1b shows a square cross-sectioned device pin nominally engaging a known test contact terminal.

FIG. 1c shows a round cross-sectioned device pin with an offset engaging a known test contact terminal.

FIG. 1d shows a square cross-sectioned device pin with an offset engaging a known test contact terminal.

FIG. 2a shows a perspective view of a top pin in an embodiment of the present invention.

FIG. 2b shows a front view of a top pin in an embodiment of the present invention.

FIG. 3a shows a perspective view of a bottom pin in an embodiment of the present invention.

FIG. 3b shows a front view of a bottom pin in an embodiment of the present invention.

FIG. 4a shows a perspective view of a top and bottom pin in an embodiment of the present invention.

FIG. 4b shows a front view of a top and bottom pin in an embodiment of the present invention.

FIG. 5 shows a perspective cross-sectioned view of a top plate, retainer, and bottom plate in an embodiment of the present invention.

FIG. 6a shows a front cross-sectioned view of a test contact before its engagement with a device pin in an embodiment of the present invention.

FIG. 6b shows a side cross-sectioned view of a test contact before its engagement with a device pin in an embodiment of the present invention.

FIG. 7 shows a front cross-sectioned view of a test contact during its engagement with a device pin in an embodiment of the present invention.

FIG. 8 shows a view of the load board provided with contact terminals establishing an electrical connection.

FIG. 9a shows a round cross-sectioned contact pin in an embodiment of the present invention.

FIG. 9b shows a square cross-sectioned contact pin in an embodiment of the present invention.

FIG. 10a shows a round cross-sectioned contact pin with device pins that are plunged down at a horizontal offset in an embodiment of the present invention.

FIG. 10b shows a square cross-sectioned contact pin with device pins that are plunged down at a horizontal offset in an embodiment of the present invention.

### REFERENCE LIST

Top pin/top contact pin (10)
Upper end (102)
Lower end (104)
Top pin first arm (12)
Top pin first arm tip (121)
Top pin second arm (13)
Top pin second arm tip (131)
Top pin bridge (14)
Top pin first leg (15)
Top pin second leg (16)
Top pin relief cavity (17)
Bottom pin/bottom contact pin (20)
Bottom pin first arm (22)
Bottom pin first arm tip (221)
Bottom pin second arm (23)
Bottom pin second arm tip (231)
Bottom pin shoulder (24)
Bottom pin first leg (25)
Bottom pin second leg (26)
Bottom pin relief cavity (27)
Bottom plate (30)
Bottom plate small hole (32)
Bottom plate large hole (33)
Retainer (40)
Retainer holes (42)
Retainer bridge (44)
Top plate (50)
Top plate holes (52)
Guide (56)
Guide holes (58)
Device pin (60)
Load board (70)

### DETAILED DESCRIPTION OF INVENTION

It should be noted that the following detailed description is directed to an electrical contact terminal for a semiconductor device testing apparatus, and is not limited to any particular size or configuration but in fact a multitude of sizes and configurations within the general scope of the following description.

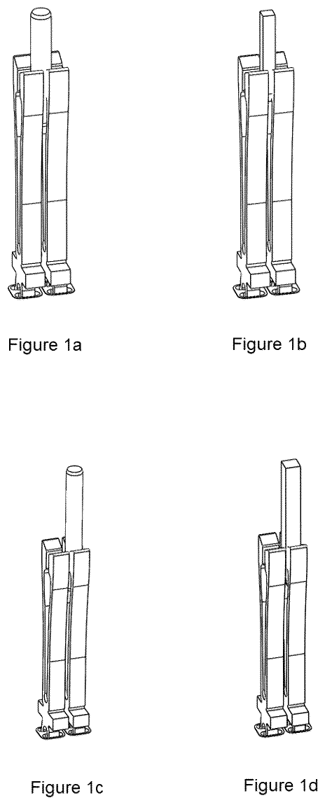

FIGS. 1a through 1d show views of a known test contact, in particular the test contact taught by Foong, et al in Malaysian patent application no. PI2023000870. In this design, two contact pins are placed parallel to each other. Each contact pin has a pair of forked arms which extend upwards to grip a device pin (60). When the device pin (60) is square or round in its cross-section, this design does not perform well. FIGS. 1a and 1b show, respectively, device pins (60) that have round and square cross-sections being lowered exactly at the centre-point of the two contact pins. In reality, the device pin (60) does not always engage the contact pins at their centre-point, and can be offset to such an extent that the device pin (60) misses one of the contact pins entirely, as shown in FIGS. 1c and 1d. This is clearly a problem for kelvin testing where one contact pin is for force and the other for sense. If the device pin misses one contact pin, the test result will not be usable. Even with the device pin (60) lowered at the centre-point of the contact pins, the shape of the round cross-sectioned device pin and the size of smaller square cross-sectioned device pins reduce the contact area between the device pin (60) and the contact pins. This may also result in a failed test or inaccurate results.

The present invention overcomes the above problems with a new design of an electrical test contact terminal having a crossed pair of contact pins with each pin having a pair of upwards-extending arms that intersect perpendicularly with the pair of arms of the other pin, so that all four arms form a square configuration, with each arm at a 90° angle to the arm next to it. Either of these contact pins could be assigned to be a force pin, and the other a sense pin, in a Kelvin test configuration. The following description will describe the present invention in more detail. The terms ‘test contact pins’ and ‘contact pins’ refer to the same thing, which is the crossed pair of contact pins of this invention forming part of the testing apparatus, whereas ‘device pin’ refers specifically to the contact pin of the IC device being tested.

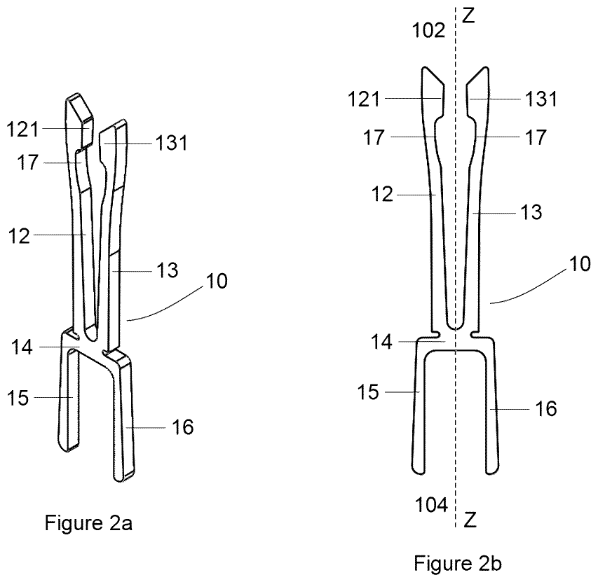

Referring to FIGS. 2a and 2b, there is shown a top contact pin (10) elongated along a Z-Z (or vertical) axis, having an upper end (102) and a lower end (104). A forked pair of arms extends upwards from a bridge (14). The pair of arms comprises a first arm (12) extending to a first arm tip (121) and a second arm (13) extending to a second arm tip (131). This pair of arms is flexible to an extent, so that when a device pin is lowered in between the tips (121, 131) during a test, the arms (12, 13) can flex enough to receive the device pin in between the tips (121, 131). The arms (12, 13) are designed to have an inward bias or grip on the device pin once it is received between the tips (121, 131), thus improving an electrical connection between the device pin and the top pin (10). The top pin (10) is provided with a pair of relief cavities (17). Each relief cavity is a concave portion located on an inside surface of each arm (12, 13), just below the tips (121, 131). This creates a profile on the inside surface of each arm that allows only a portion of the inside surface of each arm at the tips (121, 131) to be in contact with the device pin. This significantly reduces any stresses on the arms (12, 13) caused by the device pin having a lateral or angular deviation.

Still referring to FIGS. 2a and 2b, there is also provided on the top pin (10) a pair of legs comprising a first leg (15) and a second leg (16), each leg extending downwards from opposite ends of the horizontal bridge (14) towards the lower end (104). The pair of top pin legs (15, 16) fork in a direction parallel to the direction in which the top pin arms (12, 13) fork. The legs (15, 16) are the top pin's means of establishing an electrical connection with a load board of the testing apparatus.

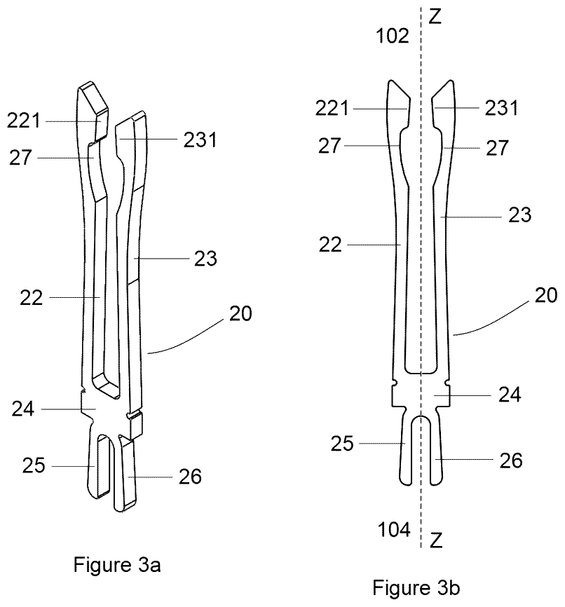

Referring now to FIGS. 3a and 3b, there is shown a bottom pin (20) elongated along a Z-Z (or vertical) axis, having an upper end (102) and a lower end (104). A forked pair of arms extends upwards from a shoulder (24). The pair of arms comprises a first arm (22) extending to a first arm tip (221) and a second arm (23) extending to a second arm tip (231). This pair of arms is flexible to an extent, so that when a device pin is lowered in between the tips (221, 231) during a test, the arms (22, 23) can flex enough to receive the device pin in between the tips (221, 231). The arms (22, 23) are designed to have an inward bias or grip on the device pin once it is received between the tips (221, 231), thus improving an electrical connection between the device pin and the bottom pin (20). Like the top pin, the bottom pin (20) is provided with a pair of relief cavities (27). Each relief cavity is a concave portion located on an inside surface of each arm (22, 23), just below the tips (221, 231). This creates a profile on the inside surface of each arm that allows only a portion of the inside surface of each arm at the tips (221, 231) to be in contact with the device pin. This significantly reduces any stresses on the arms (22, 23) caused by the device pin having a lateral or angular deviation.

Still referring to FIGS. 3a and 3b, there is also provided on the bottom pin (20) a pair of legs comprising a first leg (25) and a second leg (26), each leg extending downwards from the shoulder (24) towards the lower end (104). The pair of bottom pin legs (25, 26) fork in a direction parallel to the direction in which the bottom pin arms (22, 23) fork. The legs (25, 26) are the bottom pin's means of establishing an electrical connection with a load board of the testing apparatus.

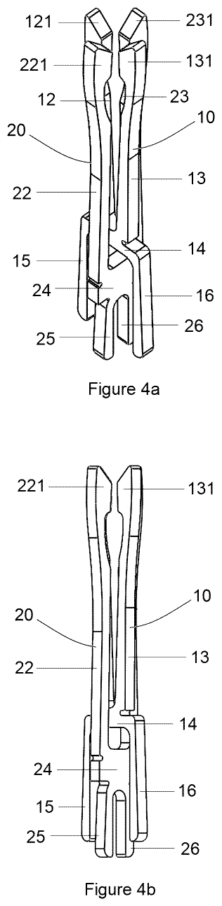

Now referring to FIGS. 4a and 4b, there is shown the top pin (10) and bottom pin (20) as they would appear once assembled. In reality, the assembled test contact is held in place using several plates (described below), but as this obscures the lower part of the pins, FIGS. 4a and 4b is used to show clearly how the top pin (10) and bottom pin (20) are arranged in relation to each other. It can be seen in these figures that the bridge (14) and top pin legs (15, 16) saddle over and perpendicularly across the bottom pin shoulder (24), without making contact. The bridge (14) and top pin arms (12, 13) intersect perpendicularly with the shoulder (24) and bottom pin arms (22, 23), thus resulting in the tips (121, 131, 221, 232) forming a square configuration when viewed downwards, with each arm being 90° rotated from the one next to it. It can also be seen that the bottom pin legs (25, 26) have a narrower fork compared to the top pin legs (15, 16), since the top pin legs (15, 16) need to be wide enough to clear the bottom pin shoulder (24).

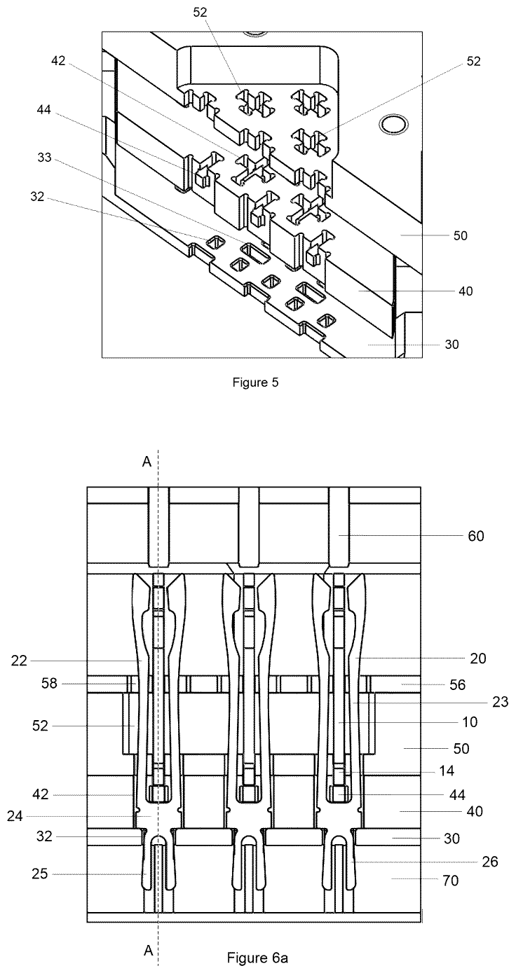

It was mentioned above that the assembled test contact is held in place using several plates. These plates are shown in FIG. 5 without the contact pins (10, 20) also to show a clear, unobstructed view of these elements. Referring to FIG. 5, there is shown a bottom plate (30) having a plurality of small holes (32) and large holes (33) pierced through the bottom plate (30). The small holes (32) are square in shape, and each small hole (32) is adapted to receive through it, a top pin leg. The large holes (34) are rectangular in shape, and each large hole (34) is adapted to receive through it, a pair of bottom pin legs. A retainer plate (or just ‘retainer’) (40) is provided with holes (42) pierced through the retainer (40). Each retainer hole (42) has a cross-shaped opening at its top. Each retainer hole (42) is provided with a retainer bridge (44) located at an intermediate depth of the retainer hole (42). The retainer bridge (44) is made from an electrically insulative material, and is located in between the top pin bridge and the bottom pin shoulder, once the test contact is assembled. It is used to keep those two elements separate from each other, both physically and electrically.

A top plate (50) is provided with a plurality of cross-shaped holes (52) pierced through the top plate. Each top plate hole (52) is adapted to receive a pair of top pin arms and a pair of bottom pin arms through it. The top plate (50) also functions to stop the top pin from moving upwards, by virtue of the top plate hole (52) having two slightly shorter arms of the ‘cross’, which allow the top pin arms to pass through, but not the top pin bridge from passing through, thus keeping the top pin from moving upwards once the test contact is assembled for a test. The size, shape, and depth of each top plate hole (52) is used to restrict and control horizontal movement of the top and bottom pin arms to within a desired range.

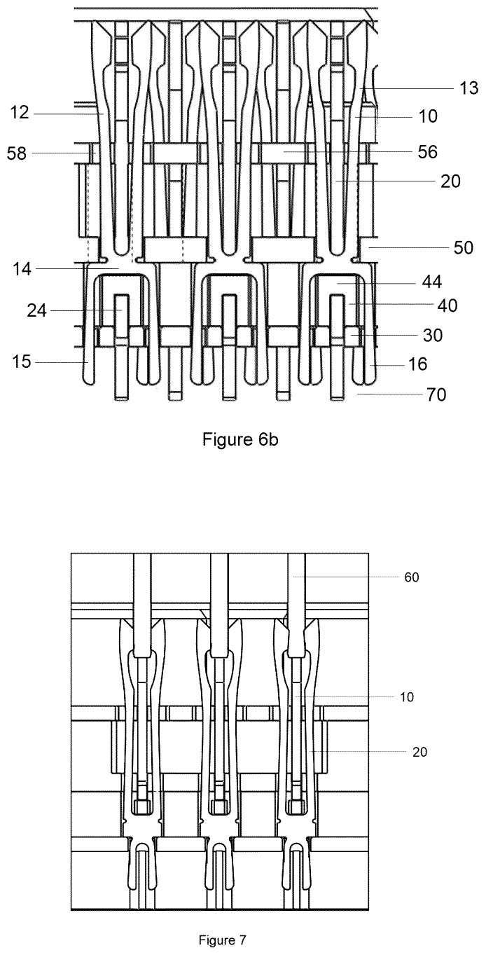

FIGS. 6a and 6b show cross-sectioned views of the same test contact of this invention, fully assembled and awaiting a test where a device lead (60) would be lowered down towards the centre (or as close to centre as possible) of the contact pin arms. FIG. 6a shows a cross-sectioned view where the cross-sectional cut has been made along a plane that is parallel to the flat side of the bottom pin (20), or in other words, the plane parallel to the direction that the bottom pin's arms (22, 23) are forked. The cut is also precisely where a row of bottom pins (20) are, so that the entire profile of the bottom pin (20) is visible. FIG. 6b, on the other hand, does the same but with the top pin (10). This means that FIGS. 6a and 6b are rotated 90° from each other around the vertical axis. FIG. 6b is also the view of plane A-A from FIG. 6a. This is the easiest way to illustrate the 3-dimensional nature of the crossed pin design of this invention.

Referring now to FIGS. 6a and 6b, there is shown the top pin (10) and bottom pin (20) securely fixed in the assembly. The bottom plate holes (32) allow the top pin legs (15, 16) and the bottom pin legs (25, 26) to pass through, while the bottom plate (30) itself restricts downwards movement of the bottom pin (20) due to the hard stop between the bottom pin shoulder (24) and the bottom plate (30). The retainer (40) is positioned immediately above the bottom plate (30). The retainer holes (42) allow the top pin bridge (14), top pin arms, bottom pin shoulder (24), and bottom pin arms to pass through. Each retainer bridge (44) rests in between a top pin bridge (14) and a bottom pin shoulder (24), keeping them separate from each other. The top plate (50) is positioned immediately above the retainer (40). The top plate holes (52) allow the top pin arms (12, 13) and the bottom pin arms (22, 23) to pierce through. The top plate (50) restricts upwards movement of the top pin (10) due to the hard stop between the top pin bridge (14) and the top plate (50). With these elements, the contact pins (10, 20) are secured in place by the bottom plate (30), retainer (40) and top plate (50), and the assembly is now a workable embodiment of this invention. If additional restriction or more precise control of the horizontal movement of the contact pin arms (12, 13, 22, 23) is required, then another plate located further up the height of the contact pin arms (12, 13, 22, 23) is used. There is thus also shown in FIGS. 6a and 6b another plate called the guide plate (56), which is positioned above the top plate (50), at a location higher up the contact pin arms (12, 13, 22, 23). The guide plate (56) is provided with a plurality of holes (58) pierced through it. As was the case for the top pin holes (52), the size, shape, and depth of the guide plate holes (58) are used to further restrict and control horizontal movement of the contact pin arms (12, 13, 22, 23) to within a desired range. In some cases, the guide plate holes (58) may work together with the top pin holes (52) to restrict and control horizontal movement of the top and bottom pin arms to within a desired range.

FIG. 7 shows a cross-sectioned view of the test contact of this invention, similar to FIG. 6a, but with the test in progress and the device lead (60) already lowered down into the contact pins (10, 20).

FIG. 8 shows a view of the load board (70). The load board (70) is provided with contact terminals (72) that contact with the contact pin legs so that electrical connection is established between them. Each load board terminal (72) is an electrically conductive hole adapted to receive one contact pin leg to a sufficient depth that a desired amount of electrical connection is established between the load board terminal and the contact pin.

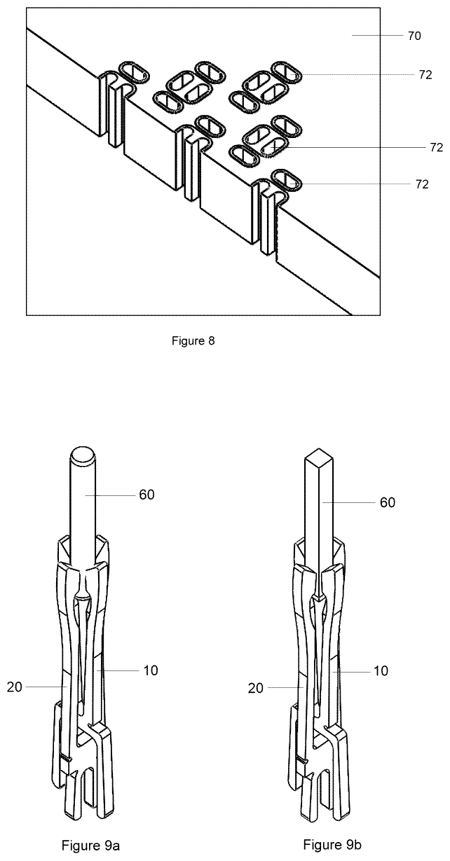

FIGS. 9a and 9b show the contact pins of this invention when testing a device pin (60) with a square and a round cross-section, respectively. These figures are illustrated without the supporting plates of a full assembly, again to provide an unobstructed view of the contact pins (10, 20). In these figures, the device pins (60) are plunged down at an optimal position, that is, a position very close to the centre point of the contact pins (10, 20) when viewed from above. These figures show how much more contact area there is between the device pin (60) and the contact pins (10, 20) in the crossed contact pin design of this invention, compared to a parallel contact pin design such as the one mentioned as prior art and shown in FIGS. 1a and 1b.

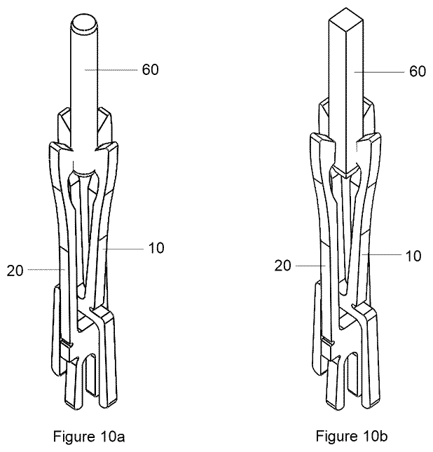

FIGS. 10a and 10b show a similar set up as the one shown in FIGS. 9a and 9b, except that in these figures, the device pins (60) are plunged down at a horizontal offset of 0.5 mm from the optimal position. Even with this significant offset, the contact area there remains good, and especially so when compared to how the parallel contact pin design handles the same offset as shown in FIGS. 1c and 1d.

While several particularly preferred embodiments of the present invention have been described and illustrated, it should now be apparent to those skilled in the art that various changes and modifications can be made without departing from the scope of the invention. Accordingly, the following claims are intended to embrace such changes, modifications, and areas of application that are within the scope of this invention.

1. An electrical contact in a testing apparatus for detachably connecting with an integrated circuit (IC) device pin (60), comprising:
a top pin (10) extending along a vertical axis (ZZ) between an upper (102) and a lower (104) end and having a forked pair of arms (12, 13) extending upwards from a bridge (14) and ending in arm tips (121, 131), said arm tips (121, 131) adapted to receive the device pin (60) in between thereof, and the top pin (10) having a means of establishing an electrical connection with a load board (70) of the testing apparatus; and
a bottom pin (20) also extending along the vertical axis (ZZ) between the upper (102) and lower (104) ends and having a forked pair of arms (22, 23) extending upwards from a shoulder (24) and ending in arm tips (221, 231), said arm tips (221, 231) substantially at the same height as the top pin arms tips (121, 131) and said arm tips (221, 231) adapted to receive the device pin (60) in between thereof, and the bottom pin (20) having a means of establishing an electrical connection with the load board (70),
wherein the top pin arms (12, 13) are forked in a direction that is substantially perpendicular to the direction in which the bottom pin arms (22, 23) are forked, so that each arm tip is at a 90° angle to the one next to it, when viewed along the vertical axis.

2. The electrical contact of claim 1, wherein the top pin's (10) means of establishing an electrical connection with the load board (70) comprises a forked pair of legs (15, 16) extending downwards from the bridge (14), the top pin legs (15, 16) forked in a direction parallel to the direction in which the top pin arms (12, 13) are forked, and wherein the bottom pin's (20) means of establishing an electrical connection with the load board (70) comprises at least one leg (25, 26) extending downwards from the shoulder (24).

3. The electrical contact of claim 1, wherein the top pin's (10) means of establishing an electrical connection with the load board (70) comprises a forked pair of legs (15, 16) extending downwards from the bridge (14), the top pin legs (15, 16) forked in a direction parallel to the direction in which the top pin arms (12, 13) are forked, and wherein the bottom pin's (20) means of establishing an electrical connection with the load board (70) comprises a forked pair of legs (25, 26) extending downwards from the shoulder (24), the bottom pin legs (25, 26) forked in a direction parallel to the direction in which the bottom pin arms (22, 23) are forked.

4. The electrical contact of claim 1, wherein the bridge (14) is saddling across but not in contact with the shoulder (24).

5. The electrical contact of claim 1, further comprising a retainer bridge (44) composed of an electrically insulative material placed in between the top pin bridge (14) and the bottom pin shoulder (24).

6. The electrical contact of claim 1, further comprising at least one plate (50, 56), each said at least one plate provided with at least one hole (52, 58), through which at least one hole the arms (12, 13, 22, 23) pierce, said at least one hole (52, 58) adapted in its shape to limit horizontal movement of the arms (12, 13, 22, 23) to within a desired range.

7. The electrical contact of claim 1, wherein each arm (12, 13 and 22, 23) is provided on an inside surface thereof with a relief cavity (17, 27) just below its arm tip (121, 131, 221, 231), said relief cavity (17, 27) allowing only a portion of the inside surface near the upper end of the arms to be in contact with the device pin (60).

8. The electrical contact of claim 1, wherein during a test, as the device pin (60) is lowered towards the contact pins (10, 20), it connects with at least one top pin arm (12, 13) and at least one bottom pin arm (22, 23).

9. The electrical contact of claim 1, wherein the top pin (10) and bottom pin (20) are not in contact with each other.

10. The electrical contact of claim 2, wherein the load board (70) is provided with terminals (72) for electrically connecting with the legs (15, 16, 25, 26), wherein each said terminal (72) comprises an electrically conductive hole adapted to receive one leg (15, 16, 25, 26) to a depth sufficient to establish a desired amount of electrical connection between the load board terminal (72) and the leg (15, 16, 25, 26).
